(19) United States
(12) Patent Application Publication
(10) Pub. No.: US 2012/0126384 A1
(43) Pub. Date: May 24, 2012

(54) PACKAGE STRUCTURE

(75) Inventor: Shang-Shin MENG, New Taipei City (TW)

(73) Assignee: GREEN SOLUTION TECHNOLOGY CO., LTD., New Taipei City (TW)

(21) Appl. No.: 13/231,967

(22) Filed: Sep. 14, 2011

(30) Foreign Application Priority Data
Nov. 23, 2010 (TW) 099140266

(51) Int. Cl. H01L 23/495

(52) U.S. Cl. 257/670; 257/E23.052

(57) ABSTRACT

The present invention employs tie bar(s) of a lead frame as contact(s) so as to increase the number of contacts in a package structure. Therefore, a die can be packaged in a package structure with a smaller dimension to lower packaging cost of an integrated circuit.

### RELATED APPLICATIONS

This application claims priority to Taiwan Application Serial Number 099140266, filed Nov. 23, 2010 which is herein incorporated by reference.

### BACKGROUND OF THE INVENTION

(1) Field of the Invention

This invention relates to a package structure, and more particularly relates to a package structure with bonding wires for electrically connecting tie bars and the die.

(2) Description of the Prior Art

After finishing the process of fabricating an integrated circuit on a die, a packaging process is usually demanded for protecting the fragile die from outside damages. In the beginning, a wafer is sliced into a plurality of dies. Then the die is placed on a lead frame, and a conductive pad on the die is wire bonded to pins of the lead frame. Afterward, the die is covered by the packaging material. Thus, the package structure can provide a stiff shell body for protecting the die located therein from the damages of moisture, heat, or noise. On the other hand, the package structure must be able to allow the exchange of signals between the die and the outside of the package structure. For achieving the above two objects, the lead frame plays an important role.

FIG. 1 is a typical wire-bonded lead frame before being cut into pieces. As shown in FIG. 1, a die 10 is adhered on a die pad 20. A tie bar 25 connecting the die pad 20 and a rail 30 is utilized for supporting the die pad 20. A pin 40 is connected to a dam bar 35, and the dam bar 35 is connected to the rail 30 for supporting the pin 40. The bonding wires 45 are utilized for electrically connecting bonding pads 15 on the die 10 to the pins 40. The wire-bonded lead frame is then cut and separated into pieces after encapsulation.

The trend for the development of integrated circuit (IC) technology is directed to high layout integration for reducing die size and material cost. However, the dimension of package structure is restricted by the increasing number of pins demanded for the die with various functions. Because packaging cost reaches about 50% of chip cost, cost saving by the reduction of die size is limited. Thus, it is an important issue for the development of IC technology to figure out a method for further reducing the cost under the limitations mentioned above.

### SUMMARY OF THE INVENTION

According to the aforementioned restrictions, the present invention uses tie bars of a lead frame as contacts for connecting a die such that the number of available contacts can be increased and the die can be packaged in a package structure with a smaller dimension, thus reducing packaging cost.

For achieving the aforementioned object, a package structure is provided in accordance with an embodiment of the present invention. The package structure has a die pad, a die, a set of contacts, and at least one tie bar. The die is located on the die pad. The contacts are spaced apart from the die pad. The tie bar is connected to the die pad. The die is wire bonded to the contact by using at least one first conductive wire, and is wire-bonded to the tie bar by using at least one second conductive wire.

Another package structure is also provided in accordance with another embodiment of the present invention. The package structure has a plurality of die pads, a plurality of dies, a set of contacts, and at least one tie bar. The contacts are spaced apart from the die pads. The dies are located on the die pads respectively, and are wire bonded to the contacts by using a plurality of first conductive wires. The tie bar is connected to at least one of the plurality of die pads, and is wire-bonded to at least one of the plurality of dies by using at least one second conductive wire.

### BRIEF DESCRIPTION OF THE DRAWINGS

The present invention will now be specified with reference to its preferred embodiment illustrated in the drawings, in which:

FIG. 1 is a typical wire-bonded lead frame before being cut into pieces;

FIG. 2 is a schematic view of a package structure in accordance with a first preferred embodiment of the present invention;

FIG. 3 is a schematic view of a package structure in accordance with a second preferred embodiment of the present invention; and

FIG. 4 is a schematic view of a multi-chips package structure in accordance with a third preferred embodiment of the present invention.

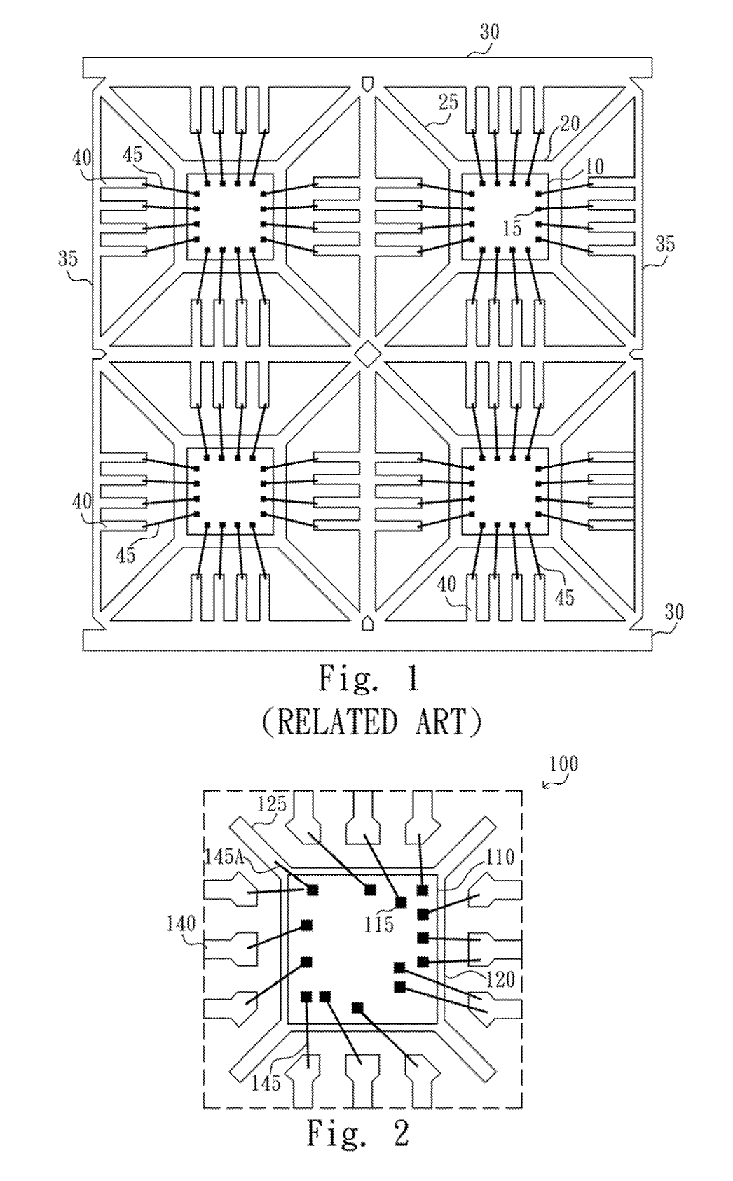

### DESCRIPTION OF THE PREFERRED EMBODIMENT

FIG. 2 is a schematic view of a package structure in accordance with a first preferred embodiment of the present invention. As shown in FIG. 2, the package structure 100 has a die 110, a die pad 120, a set of contacts 140, and at least one tie bar 125. The die 110 is located on the die pad 120. A plurality of conductive pads 115 are located on an upper surface of the die 110 as a signal input or a signal output for the circuit within the die 110. The contacts 140 are wire bonded to the conductive pads 115 on the die 110 by using first conductive wires 145, such that the die 110 is electrically connected to an external circuit through the contacts 140 for outputting or receiving signals. The tie bar 125 is connected to the die pad 120 for supporting the die pad 120 until the lead frame is cut into pieces. In the present embodiment, the package structure is a QFN 2×2 package structure with twelve contacts 140 (three contacts on each side of the package structure) and four tie bars 125 aligned to the four corners of the package structure. Some of the conductive pads 115 on the die 110 are wire bonded to the tie bars 125 through second conductive wires 145A. In the present embodiment, one conductive pad 115 is electrically connected to the tie bar 125, and thus, thirteen contacts in total are provided in the QFN 2×2 package structure of the present embodiment. In addition, by using the tie bar 125 as another contact, the idea of the present invention may be applied to a typical lead frame without the needing to change the model of the lead frame. Thus, the package structure provided in the present embodiment is quite suitable for the present package process.

FIG. 3 is a schematic view of a package structure in accordance with a second preferred embodiment of the present invention. A major feature of the present embodiment different from the embodiment in FIG. 2 is described below. As shown in FIG. 3, the integrated circuit layout of the die 110 includes a control circuit 105A and a driving circuit 105B. The control circuit 105A is utilized for receiving the input signals from the outside and for controlling the operation of the driving circuit 105B according to the input signals. The driving circuit 105B is utilized for driving outside circuits, such as integrated circuit or MOSFET transistors. Because of driving requirements, the power demanded for the driving circuit 105B is much greater than that for the control circuit 105A. If the two circuits 105A and 105B are connected to the same contact for receiving driving power, the noise resulted from the driving circuit 105B may interfere with the operation of the control circuit 105A. Thus, two separate contacts are provided as the power inputs for the control circuit 105A and the driving circuit 105B respectively. In the present embodiment, the control circuit 105A and the driving circuit 105B are wire bonded to two different tie bars 125 by using the second conductive wires 145A for receiving the power from a common driving power source. Preferably, the two tie bars 125 may be the tie bars 125 located at the diagonally opposite corners of the package structure. Because the two tie bars 125 for electrically connecting the control circuit 105A and the driving circuit 105B are not connected directly, the noise generated by the driving circuit 105B is attenuated by the intermediate circuit elements (such as the die pad 120) between the two tie bars 125 before reaching the control circuit 105A. Thus, the undesirable affects of noise to the control circuit 105A can be significantly reduced. In the present embodiment, the two tie bars 125 are electrically connected to the conductive pads 115, and thus, fourteen contacts are provided in the QFN 2×2 package structure of the present embodiment. In addition, the number of tie bars 125 electrically connected to the die pad 120 and the way for fixing the die 110 on the die pad 120 may be varied according to the circuit design on the die 110. For example, the die 110 may be adhered to the die pad 120 by using conductive glue or insulation glue.

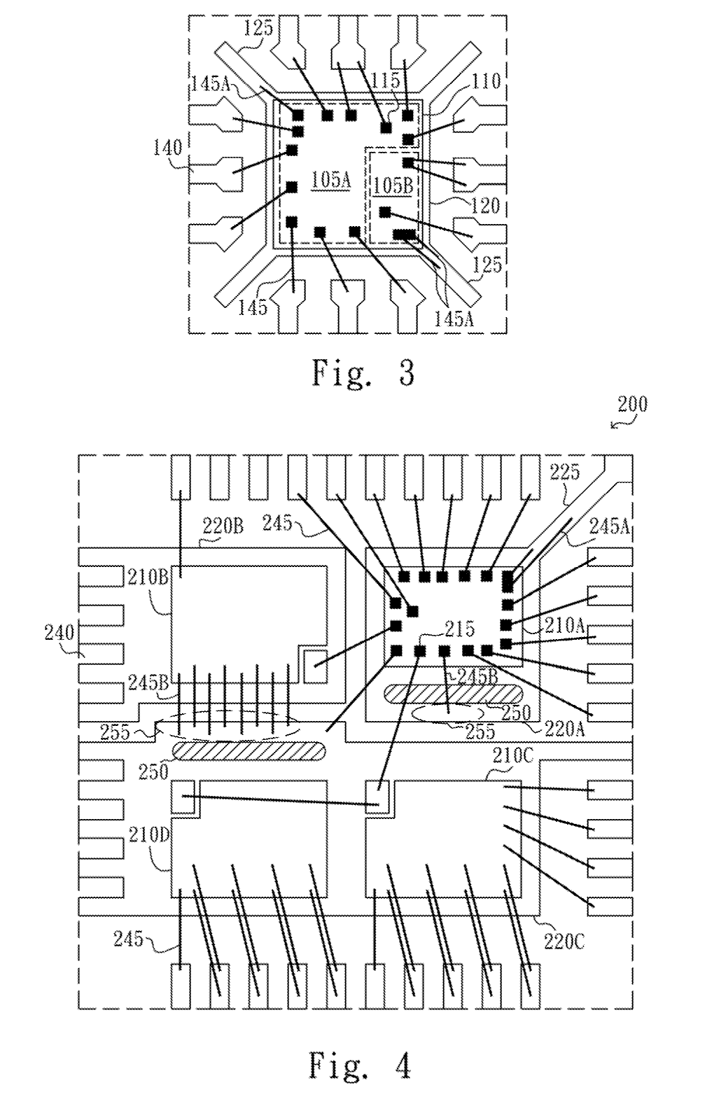

FIG. 4 is a schematic view of a multi-chips package structure in accordance with a third preferred embodiment of the present invention. As shown in FIG. 4, a package structure 200 has a plurality of die pads 220A, 220B and 220C, a plurality of dies 210A, 210B, 210C and 210D, a set of contacts 240, and at least one tie bar 225. In the present embodiment, the die 210A has a control circuit formed thereon, and each of the dies 210B, 210C and 210D has a N-type MOSFET structure formed thereon, and the package structure is a QFN 5×5 package structure with forty contacts 240 (ten contacts 240 on each side of the package structure). Some of the contacts 240 are directly connected to the die pads 220B and 220C as drain contacts for the dies. Other contacts 240 are wire bonded to the dies 210A, 2106, 210C and 210D through first conductive wires 245. Some of the conductive pads 215 on the die 210A are wire bonded to the tie bar 225 by using second conductive wires 245A.

In the present embodiment, the die pad 220A and 220B also have bonding areas 255 which are located thereon and electrically connected to the dies 210A and 210B through third conductive wires 245B. As the size of the die and the die pad is reduced, excess portion of the resin for binding the die on the die pad may bleed to the boding areas to fail the wire bonding process of the third conductive wires 245B. To solve this problem, a resin bleed prevention structure 250 is formed between the die attach area (with respect to the location of the die) and the bonding area 255 to prevent resin bleeding to the boding area 255, thereby guaranteeing enough space for wire bonding. The resin bleed prevention structure 250 may be a groove or a bump.

In conclusion, the present invention using the tie bar of the lead frame as the contact for increasing the number of available contacts is helpful for packaging a given die into a smaller package structure. Thus, the packaging cost as well as the total fabrication cost of the IC can be reduced.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A package structure, comprising:
a die pad;
a die located on the die pad;
a set of contacts spaced apart from the die pad; and
at least one tie bar connected to the die pad for supporting the die pad before the at least one tie bar being cut;
wherein the die is wire bonded to the contact by using at least one first conductive wire, and is wire bonded to the tie bar by using at least one second conductive wire.

2. The package structure of claim 1, wherein an integrated circuit layout on the die includes a control circuit and a driving circuit, and the tie bars include a first tie bar and a second tie bar, and the driving circuit is wire bonded to the first tie bar through the second conductive wire.

3. The package structure of claim 2, wherein the die is adhered to the die pad.

4. The package structure of claim 2, wherein the control circuit is wire bonded to the second tie bar by using the second conductive wire.

5. The package structure of claim 4, wherein the package structure has twelve contacts with respect to the die pad.

6. The package structure of claim 1, wherein the package structure has twelve contacts with respect to the die pad.

7. A package structure, comprising:
a plurality of die pads;
a set of contacts spaced apart from the die pads;
a plurality of dies which is located on the die pads respectively and wire bonded to the contacts by using a plurality of first conductive wires; and
at least one tie bar which is connected to at least one of the die pads for supporting the die pad before the at least one tie bar being cut and is wire bonded to at least one of the plurality of dies by using at least one second conductive wire.

8. The package structure of claim 7, wherein the dies include a first die with a control circuit formed thereon and a second die with a MOSFET structure formed thereon, and the first die is wire bonded to the tie bar through the second conductive wire.

9. The package structure of claim 8, wherein at least one of die pads includes a first die has a bonding area, a resin bleed prevention structure, and a die attach area, and the resin bleed prevention structure is located between the bonding area and the die attach area for preventing resin bleed flowing to the bonding area, and the bonding area is wire bonded to one of the die pads.

10. The package structure of claim 7, wherein at least one of the die pads includes a first die has a bonding area, a resin bleed prevention structure, and a die attach area, and the resin bleed prevention structure is located between the bonding area and the die attach area for preventing resin bleed flowing to the bonding area, and the bonding area is wire bonded to one of the die pads.

11. The package structure of claim 10, wherein the resin bleed prevention structure is a groove.

12. The package structure of claim 10, wherein the resin bleed prevention structure is a bump.
